(19) United States
(12) Patent Application Publication
(10) Pub. No.: US 2002/0090045 A1
(43) Pub. Date: Jul. 11, 2002

(54) Digital clock recovery system

(76) Inventor: Norm Hendrickson, Colorado Springs, CO (US)

Correspondence Address: CHRISTIE, PARKER & HALE, LLP, P.O. BOX 7068, PASADENA, CA, 91109-7068, US

(21) Appl. No.: 10/037,671

(22) Filed: Jan. 3, 2002

Related U.S. Application Data
(60) Provisional application No. 60/261,868, filed on Jan. 10, 2001.
(60) Provisional application No. 60/272,635, filed on Feb. 28, 2001.
(60) Provisional application No. 60/273,763, filed on Mar. 5, 2001.

(51) Int. Cl. H03D 3/24

(52) U.S. Cl. 375/376

(57) ABSTRACT

A digital clock recovery circuit. The digital clock recovery circuit uses a lumped delay line and a digital phase detector to form a recovered clock signal. The recovered clock signal is limited to one clock period of the delay line so as to prevent false locking.

### CROSS-REFERENCE TO RELATED APPLICATIONS

This application claims the benefit of U.S. provisional application No. 60/261,868, filed Jan. 10, 2001, No. 60/272,635, filed Feb. 28, 2001, and No. 60/273,763, filed Mar. 5, 2001 which are hereby incorporated by reference as if set forth in full herein.

### BACKGROUND

The present invention relates generally to data communication, and more particularly to clock recovery from a data steam.

Digital communication systems transmit large amounts of data. The data is often transmitted without an accompanying clock signal, thereby allowing for increased bandwidth as any transmitted clock signal takes the place of data. Often the data is a non-return to zero (NRZ) format, although at times other formats such as return to zero (RZ) are used.

Generally a receiver recovers a clock signal from the transmitted data through the use of a phase locked loop (PLL) or variations thereof. PLL's are used to generate periodic signals which maintain a constant phase angle to a reference signal. PLL's are often are formed using a phase detector which, with other circuitry, controls an oscillator generating a periodic signal. For clock recovery from a transmitted data stream the periodic signal matches transitions in a data signal. Thus, for example, PLLs often use a locally generated clock signal, generated for example by a voltage controlled oscillator (VCO), and adjust the output of the VCO to match the phase of the incoming data stream. The output of the VCO is adjusted based on comparison of the data transitions of the incoming data signal with transitions of the clock signal.

PLL's generally require the use of analog components, which are sometimes unavailable to circuit designers. This may occur, for example, when designers are restricted to use predefined libraries of digital gates. Thus, such designers may be limited in their ability to provide a clock recovery system appropriate for their uses.

In addition, effective clock recovery often faces many difficulties. Due to process variations and temperature changes the transmitter may transmit data at frequencies slightly different than that expected, and the frequency may change over time. Similarly, a receiving system faces similar problems, such that even if clock recovery is effectively accomplished at one time by one system at other times and for another system varying results may be achieved. This may vary by system as well as over time.

A further problem in clock recovery is that a clock recovery system may inadvertently set itself to an incorrect frequency and phase, sometimes referred to as false locking. False locking may occur, for example, when a system locks onto a harmonic or partial harmonic of the actual clock. This may occur for several reasons, one of which is that the data signal does not always exhibit constant data transition density. In addition, the data eye formed by a multitude of data transitions may be irregular in shape, with the center of the data eye not necessarily corresponding to the center of the clock. Moreover, the local clock signal may also be irregular in shape, further complicating data recovery.

### BRIEF DESCRIPTION OF THE DRAWINGS

FIG. 1 illustrates a block diagram of one embodiment of a digital clock recovery system of the present invention;

FIG. 2 illustrates a block diagram of another embodiment of a digital clock recovery system of the present invention; and

FIG. 3 illustrates a circuit diagram of one embodiment of the clock and data recovery system in accordance with the present invention.

### DETAILED DESCRIPTION

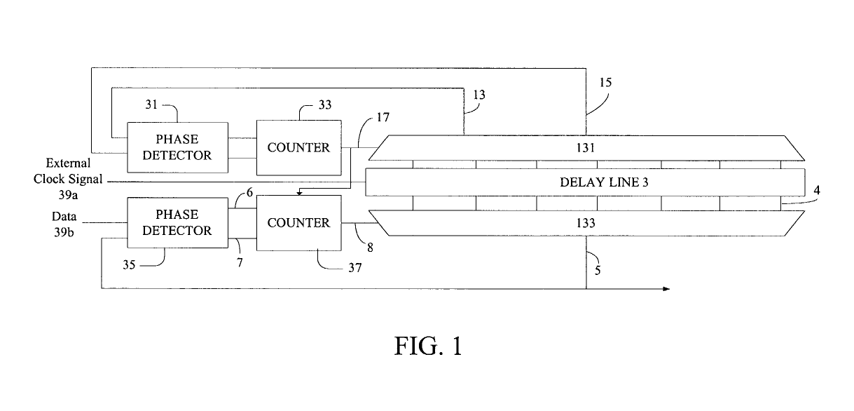

FIG. 1 illustrates a clock recovery unit in accordance with aspects of the present invention. In the clock recovery unit of FIG. 1, a clock signal, such as a local reference clock signal, or as iin FIG. 1 an external clock signal 39a is provided to a clock phase generator. As illustrated, the clock phase generator is a lumped delay line 3 formed of a series of lumped delay elements. Taps 4 are taken between each of the lumped delay elements. Each successive tap, therefore, is a signal which is slightly delayed with respect to a signal from the preceeding tap. As the signal is a clock signal, each tap has a slightly delayed, or phase-shifted, version of the clock signal.

The phase-shifted clock signal is used to form a recovered clock signal 5. Which of the phase-shifted clock signals used at any given time is determined by comparing transitions of a currently selected phase-shifted clock signal with data transitions in an incoming data stream. The comparison is performed by a phase detector 35, with the phase detector generating an up signal 6 and a down signal 7.

The up/down signals are provided to a counter 37. The counter 37 accumulates up/down signals to form a selector signal 8. The selector signal determines which tap a selector circuit 133 selects for use from the lumped delay line. In addition, the counter, in this instance, counts in a rollover fashion. That is, the counter counts from zero to N−1, with the counter returning to zero when the count reaches N. As will shortly be discussed, n is determined so that the range of possible taps from the delay line ranges within one clock period of the reference clock. This provides several benefits, including a reduction in false locking, particularly at harmonics of the data signal. N is determined by the number of taps equivalent to one clock period of the reference clock.

As illustrated in the example of FIG. 1, the number of taps equivalent to one clock period of the reference clock is determined by passing a clock signal 13 from the first of the sequence of taps through selection circuitry 131 to a phase detector 31. A second phase-shifted clock signal 15 from another tap is also provided to the phase detector. The phase detector compares the clock signals, which are of the same frequency, that of the reference clock signal, but of potentially differing phases. The phase detector generates up/down signals which are provided to a counter 33. The counter generates a signal 17 to vary selection of the second clock signal. After a transient period, a steady state solution of the counter indicates the number of taps one clock period apart. As process variations may cause delay amounts provided by the lumped delay elements or other circuit elements to vary, and the various delays may change with temperature or other factors as well, the reference phase detector and counter accommodate changes between parts and/or within the same part over time.

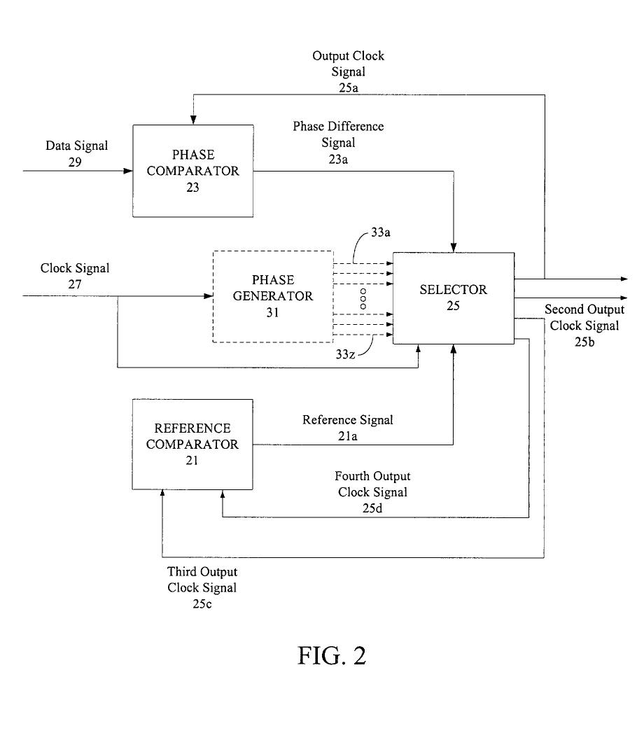

FIG. 2 illustrates a block diagram of further embodiments of a clock recovery system of the present invention. In the system of FIG. 2 a plurality of clock signals 33a-z, differing in phase, are generated by a phase generator 31 using a reference clock signal 27. The phase generator, in various embodiments, includes a signal delay line formed of various circuit embodiments, including in some embodiments latches forming a FIFO. The plurality of clock signals are provided to a selector 25. The selector selects an output clock signal 25a, with the output clock signal forming a recovered clock signal.

The selector selects the output clock signal based on a phase difference signal 23a. The phase difference signal is generated by a phase comparator 23, which compares the phase of the output clock signal with the phase of a data signal 29. The phase comparator, therefore, acts as a phase detector, and in one embodiment is a phase detector.

In order to assist in preventing locking at harmonics of the clock signal used to generate the data signal, however, a reference signal is also used. The reference signal is used to determine a range of phase signals generated by the phase generator which are within one period of the reference clock signal.

The reference signal, in one embodiment, is formed by a reference comparator 21 which compares the phases of a zeroth phase signal, e.g., a fourth output clock signal 25d, with that of a further selected phase signal, e.g., a third output clock signal 25c. The reference signal drives the selector to match the phases of the zeroth phase signal with that of the further selected phase signal. The difference between the selection of the two signals therefore identifies one period of the reference clock signal, which is about the frequency of the clock signal used to generate the data signal. The selector uses this identification to bound the output clock signal within that period.

FIG. 2 is also illustrative of different embodiments of the invention. In one such embodiment the clock control system includes a reference comparator 21, a phase comparator 23 and a selector 25. The selector 25 receives a clock signal 27. In one embodiment, a clock multiplier (not shown) accelerates the frequency of the clock signal and thereby generates a higher frequency clock signal. The selector, using the received clock signal, generates a series of output clock signals 25a -25d.

The output clock signal 25a is supplied to the phase comparator 23. The comparator is also supplied a data signal 29. The comparator determines if the first output clock signal corresponds to the phase of the data signal. Based on phase deviations or variations between the two signals determined by the comparator, the comparator generates a phase difference signal 23a. The phase difference signal is supplied to the selector 25 which, based on the received phase difference signal, adjusts the output clock signal 25a, e.g., speeds up or slows down the signal. As such the selector causes the first output clock signal to correspond with, e.g., be in phase with, the phase data signal.

The selector 25 also generates a third and fourth output clock signal 25c and 25d which is supplied to the reference comparator 21. The reference comparator determines the phase variation between the third and fourth output clock signals and generates a corresponding reference signal 21a based on the determined variation. The reference signal 21a is supplied to the selector 25. Based on the received reference signal, the selector adjusts or generates the third clock signal, such that the third and fourth output clock signals are in phase with each other. The second output clock signal 25b, in one embodiment, is generated based on the first output clock signal and the third output clock signal. For instance, the third output clock signal is approximately half a clock period out of phase of the third clock signal and offset from the frequency of the first output clock signal. Thus, a clock signal of desired duty cycle can be synthesized, or clock signals of desired phase relationship can be generated. For example, selection of a clock signal out of phase from output clock signal a fixed amount, such as ⅝ of a clock period, may be determined beneficial in performing data recovery. Also, for example, selection of the second output clock signal 90 degrees from the output clock signal may be beneficial in forming quadrature clock signals formed of the output clock signal and the quadrature clock signal.

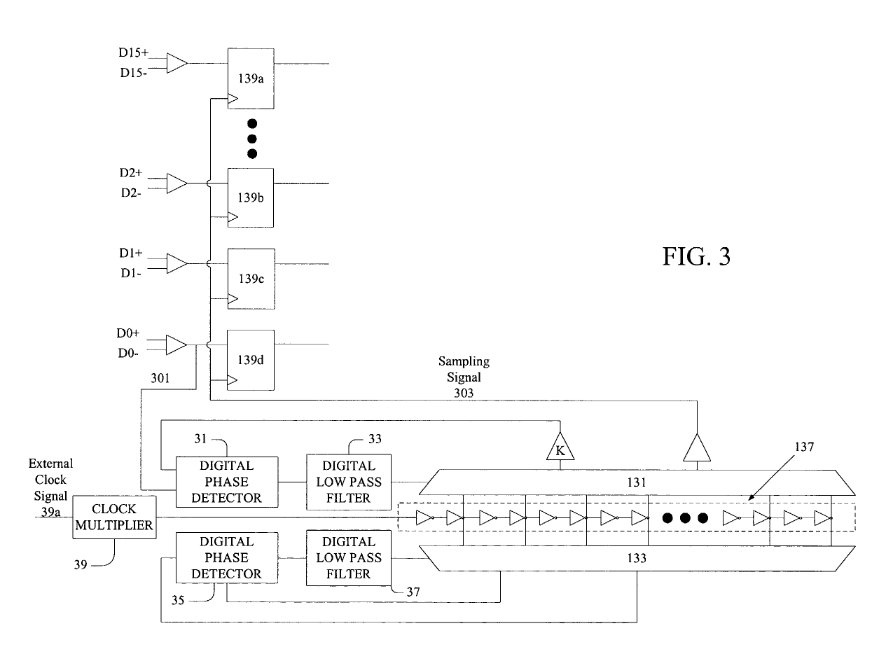

FIG. 3 illustrates a circuit diagram of a further embodiment of a clock recovery system, including that of a clock and data recovery system. The system receives an external clock signal and an input data stream and generates an output clock signal aligned with the incoming data stream. In one embodiment, the clock signal generator is comprised of digital elements relatively available in, for example, ASIC design libraries, thereby making the clock control system available in a wide variety of design environments.

In the embodiment of FIG. 3, a reference clock is passed through a delay line having multiple taps. Outputs of the multiple taps are passed to phase detectors, which provide an indication of the reference clock (which may vary with temperature, etc.) and the clock rate of an incoming data stream. An output of the multiple taps is also utilized to recover data from the incoming data stream.

More specifically, a reference clock signal 39a is supplied to a clock multiplier 39. The clock multiplier multiplies the reference clock signal to generate a clock signal having a greater frequency than the reference clock signal. In the embodiment described, the clock multiplier increases the rate of the reference clock signal to 2.5 GHz. In other embodiments, the clock multiplier increases the reference clock signal to other frequencies, for example, 622 Hz. The multiplied clock signal is supplied to a delay line 137.

The delayed line, in this embodiment, includes a plurality of sequential delay elements. A tapped output from a delay element therefore is a clock signal phase-shifted with respect to the clock signal provided at the output of the delay element. As such, different taps along the delay line generate clock signals of varying phase-shifts with respect to the input clock signal. In one embodiment, the delayed versions of the multiplied clock are mixed or interpolated to generate a clock signal with finer steps. In other words, the generated clock signal has a finer or smaller delay difference from the multiplied clock than the delayed versions of the multiplied clock that were mixed.

As illustrated in FIG. 3, two multiplexer units 131 and 133 receive outputs from the tapped delay line 137. As those of skill in the art will recognize, in actual practice differing numbers of multiplexers may be used, but the use of the two multiplexer units in FIG. 3 eases discussion. Thus, a first multiplexer unit 133 receives signals from the output taps of the delayed line. A first signal is obtained from the beginning of the delay line, the signal for convenience being termed the zero delay signal. A second signal is also tapped from the delay line, with the position of the second signal being variable. For convenience the second signal is termed the nth delay signal. The zero delay signal and the nth delay signal are provided to a phase detector 35. The phase detector compares the signals and if the signals are out of phase, generates an increment/decrement signal to command increasing or decreasing phase shift of the nth delay signal. In one embodiment, the increment/decrement signal is provided to a counter (not shown) or other circuit element, with the counter or other circuit element providing indication of the difference between the tap of the zero delay and the nth delay signal, as well as the selector signal(s) for the first multiplexer unit 133.

The phase detector therefore causes the zero delay signal and the nth delay signal to be in phase. The number of delay taps between the zero delay tap and the nth delay tap provides an indication of the clock signal provided to the tapped delay line.

In the embodiment described, the phase detector is provided to a low pass filter 37 which reduces noise on the select signal, e.g., removes high frequency harmonics, and thereby smoothes the response of the clock control system. In one embodiment, the first multiplexer unit also includes fixed selectors to check for and prevent harmonic locking of the delay line.

A second multiplexer unit 131 also receives outputs from the taps of the delayed line 37. The second multiplexer selects a kth delay signal from the delay line and produces the kth delay signal to a second phase detector 31. The second phase detector also receives data from a first data channel 301. If the signals are out of phase, the second phase detector generates the command to change the selection signal to adjust k, i.e., select a different output tap to generate the kth clock signal. As a result, the second phase detector causes the kth clock signal to be phase locked to the digital data on the first data channel. In the embodiment described, the second phase detector supplies the selection signal to a second low pass filter 33. The second low pass filter averages the phase variation which is passed to the kth clock signal. The average phase correction rate can be calculated to provide selection of updates even in the absence of data transitions in the incoming data stream. Thus, a clock signal with a frequency offset from the reference clock signal may be generated. For example, constant variation, or precession, in the selected tap may be used to generate a clock signal with a greater or a lesser frequency than the reference clock signal.

The second multiplexer unit also generates a sampling signal 303. The sampling signal is a delayed version of the kth delay signal. In general, the kth delay signal provides a clock signal with edges approximately synchronized to the data transitions in the incoming data stream. In sampling the data stream, it is preferred to sample the incoming data stream about the center, variously defined, of the data eye. Thus, assuming that a signal phase shifted half of a cycle from the kth delay signal provides an optimal sampling point the relative position of the zero delay selector and the nth delay selector may be used to determine the appropriate tap for selection for the sampling signal.

In one embodiment, therefore, the difference between the nth tap position and the zero tap position is divided by two and added (or subtracted depending on the position of the kth tap at any given moment) to the value of the kth tap position. The resulting value allows a selector to determine the tap for the sampling signal.

The components described in FIG. 3 are, in one embodiment, digital gate components readily available in a digital application specific integrated circuit (ASIC) cell library. Furthermore, no large area capacitators or tuning circuits are required in some embodiments. The circuit also provides a long run length tolerance of static “1” or “0” data, because the loop filters do not drift or change unless there is a transition at the input.

Thus, the present invention provides clock recovery systems and methods. Although this invention has been described in certain specific embodiments, many additional modifications and variations would be apparent to those skilled in the art. It is therefore to be understood that this invention may be practiced otherwise and as specifically described. Thus, the present embodiments of the present invention should be considered in all respects as illustrative and not restrictive. The scope of the invention to be determined by the appended claims, their equivalents and claims supported by the specification rather than the foregoing description.

1. A clock recovery system comprising:
a first phase detector comparing a data signal to an output signal and generating control signals based on the comparison;
a first counter receiving the control signals and selecting a clock signal based on received control signals and adjusting the output signal to correspond to the selected clock signal;
a second phase detector comparing a reference clock signal to a delayed clock signal and generating control signals based on the comparison; and
a second counter receiving the control signals and the selected clock signal and selecting an offset clock signal based on the control signals and the selected clock signal.

2. The system of claim 1 further comprising a first multiplexer generating the output signal based on the selection from the first counter.

3. The system of claim 1 further comprising a second multiplexer generating the offset clock signal based on the selection from the second counter.

4. The system of claim 1 wherein the delayed clock signal is a clock signal that is at most one clock period out of phase of the reference clock signal.

5. The system of claim 1 wherein the delayed clock signal is dependent on the offset clock signal.

6. The system of claim 1 wherein the delayed clock signal is offset by the selected clock signal and a half a clock period of the offset clock signal.

7. A clock recovery method comprising:
generating a plurality of clock signals based on a reference clock signal;
selecting one of the plurality of clock signals based on a phase signal;
generating the phase signal based on the selected plurality of clock signals and a data signal;
generating a reference signal based on a reference clock signal and a delayed clock signal; and
adjusting the selected one of the plurality of clock signals based on the generated reference signal.

8. A digital clock recovery unit with harmonic lock prevention, comprising:
a phase generator receiving a clock signal and generating multiple phase-shifted versions of the clock signal;
a reference loop including a reference phase detector comparing two of the phase-shifted versions of the clock signal and driving a reference selector to cause selection of phase-shifted versions of the clock signal phase-shifted a predetermined amount, the reference loop forming a reference selection signal indicating a clock period of the clock signal;
a clock recovery loop including a phase detector comparing a phase-shifted version of the clock signal with a data signal, the phase detector driving a selector to cause selection of a phase-shifted version of the clock signal having a constant phase with respect to the data signal;
the selector of the clock recovery loop limiting the selection of the phase-shifted version of the clock signal having a constant phase with respect to the data signal based on the reference selection signal.

9. A method of recovering a clock signal from a data stream comprising:
providing a reference clock signal approximate an expected frequency of the clock signal to a delay line;
determining a length of the delay line corresponding to a period of the reference clock signal;
iteratively selecting a recovered clock signal from the delay line based on a comparison of the recovered clock signal with a data signal, the recovered clock signal limited to a section of the delay line corresponding to the period of the reference clock signal.

10. The method of claim 9 wherein determining a length of the delay line corresponding to a period of the reference clock signal comprises comparing a first reference clock signal from a variable position on the delay line with a second reference clock signal from a fixed position on the delay line and adjusting the position of the variable position until the first reference clock signal and the second reference clock signal have a constant phase relationship.

11. The method of claim 10 wherein the constant phase relationship is zero phase difference.

12. The method of claim 11 wherein the difference in position between the fixed position and the variable position indicates the length of the delay line corresponding to one clock period of the reference clock.

13. The method of claim 12 wherein the recovered clock signal is limited to positions along the delay line from the fixed position to the variable position.

14. The method of claim 13 wherein the recovered clock signal is selected from positions along the delay line that vary at a substantially constant rate, whereby the recovered clock signal is offset in frequency from the reference clock signal.

15. The method of claim 13 further comprising determining a sampling clock signal using the recovered clock signal and a fraction of the difference between the fixed position and the variable position.

16. The method of claim 15 wherein the fraction is one-half.

17. The method of claim 15 wherein the sampling clock signal and the recovered clock signal have a phase difference of approximately 90 degrees.

18. The method of claim 13 wherein the delay line provides outputs at a fixed number of discrete points along the delay line, the difference between the fixed position and the variable position is N outputs, and the recovered clock signal is taken from output K, with the method further comprising selecting a sampling clock signal from the delay line from an output determined by adding a fixed fraction of N to K.

19. The method of claim 18 wherein the delay line provides outputs at a fixed number of discrete points along the delay line, the difference between the fixed position and the variable position is N outputs, and the recovered clock signal is taken from output K, with the method further comprising selecting a sampling clock signal from the delay line from an output determined by subtracting a fixed fraction of N to K.

20. A digital clock recovery unit comprising:
a digital phase locked loop comprising a phase detector, a low pass filter, and a delay element with a selectable output, the phase detector comparing a data signal with a selected output of the delay element to form a phase difference signal provided to the low pass filter, the low pass filter forming a selector signal to select the selected output, the selector signal being limited to a range indicated by a reference signal; and
a reference digital phase locked loop comprising a reference phase detector, a reference low pass filter, and the delay element with a reference selectable output, the reference phase detector comparing a fixed output of the delay element with a reference selected output of the delay element to form a reference phase difference signal provided to the reference low pass filter, the reference low pass filter forming a reference selector signal to select the reference selected output, the reference selector signal forming the reference signal.

21. A clock recovery system comprising:
means for generating a plurality of clock signals differing in phase;
means for comparing a selected clock signal of the plurality of clock signals with a data signal to generate a change signal;
means for varying the selected clock signal based on the change signal and a range signal; and
means for comparing a fixed clock signal of the plurality of clock signals with a variable clock signal of the plurality of clock signals to generate a range signal.
